(19) United States
(12) Patent Application Publication
(10) Pub. No.: US 2021/0257197 A1
(43) Pub. Date: Aug. 19, 2021

(54) SUBSTRATE PROCESSING METHOD, GAS FLOW EVALUATION SUBSTRATE AND SUBSTRATE PROCESSING APPARATUS

(71) Applicant: Tokyo Electron Limited, Tokyo (JP)

(72) Inventors: Risako MATSUDA, Miyagi (JP); Jun HIROSE, Miyagi (JP)

(73) Assignee: Tokyo Electron Limited, Tokyo (JP)

(21) Appl. No.: 17/178,273

(22) Filed: Feb. 18, 2021

(30) Foreign Application Priority Data
Feb. 19, 2020 (JP) 2020-026160

(51) Int. Cl. H01J 37/32; H01L 21/67; H01L 21/66

(52) U.S. Cl. CPC H01J 37/32981; H01L 21/67069; H01L 21/67253; H01J 2237/24585; H01J 37/32715; H01J 37/3244; H01J 2237/244; H01L 22/20

(57) ABSTRACT

A substrate processing method is provided. The substrate processing method includes (a) placing a substrate on a substrate support disposed in a chamber, the substrate having a plurality of flow sensors on a surface of the substrate; (b) supplying a processing gas into the chamber; and (c) measuring magnitudes and directions of flows of the processing gas on the surface of the substrate using the plurality of flow sensors.

### CROSS-REFERENCE TO RELATED APPLICATION

This application claims priority to Japanese Patent Application No. 2020-026160, filed on Feb. 19, 2020, the entire contents of which are incorporated herein by reference.

### TECHNICAL FIELD

The present disclosure relates to a substrate processing method, a gas flow evaluation substrate, and a substrate processing apparatus.

### BACKGROUND

Japanese Patent Application Publication No. H09-27456 discloses a semiconductor manufacturing apparatus in which film formation, impurity diffusion, and the like are performed by heating a semiconductor substrate in a chamber and supplying a carrier gas and a reactive gas. This semiconductor manufacturing apparatus includes a mechanism for constantly monitoring a concentration of the reactive gas in the chamber. Further, the reproducibility is improved by starting processing after the concentration of the reactive gas reaches a gas concentration set by a mass flow controller.

### SUMMARY

The technique of the present disclosure appropriately measures gas flow on a surface of a substrate.

In accordance with an aspect of the present disclosure, there is provided a substrate processing method. The substrate processing method includes (a) placing a substrate on a substrate support disposed in a chamber, the substrate having a plurality of flow sensors on a surface of the substrate; (b) supplying a processing gas into the chamber; and (c) measuring magnitudes and directions of flows of the processing gas on the surface of the substrate using the plurality of flow sensors.

### BRIEF DESCRIPTION OF THE DRAWINGS

The objects and features of the present disclosure will become apparent from the following description of embodiments, given in conjunction with the accompanying drawings, in which:

FIG. 1 is a plan view showing a schematic configuration of a wafer processing apparatus according to an embodiment;

FIG. 2 is a vertical cross-sectional view showing a schematic configuration of a processing module according to the embodiment;

FIG. 3 is a plan view showing a schematic configuration of an evaluation wafer according to an embodiment;

FIG. 4 explains a schematic configuration of a flow sensor;

FIG. 5 explains an example of a flow of a processing gas on the evaluation wafer;

FIG. 6 is a plan view showing a schematic configuration of an evaluation wafer according to another embodiment; and

FIG. 7 explains an example of a flow of a processing gas on the evaluation wafer.

### DETAILED DESCRIPTION

In a semiconductor device manufacturing process, a processing gas is supplied for a semiconductor wafer (hereinafter, may be referred to as “wafer”) and the wafer is subjected to desired processing such as etching, film formation, diffusion, or the like. Specifically, the processing gas is supplied into the chamber in a state where the wafer is held on a substrate support disposed in the chamber.

Conventionally, a gas box that is a supply source of the processing gas is disposed outside the chamber in order to control gas flow of the processing gas. The processing gas is supplied into the chamber at a flow rate divided by a flow splitter. By supplying the processing gas while controlling and dividing the gas flow thereof, gas flow on a wafer surface becomes uniform.

However, it is difficult for a conventional substrate processing apparatus to measure gas flow of a gas flowing on the surface of a wafer. For example, the semiconductor manufacturing apparatus disclosed in Japanese Patent Application Publication No. H9-27456 monitors the concentration of the reactive gas (processing gas) in the chamber, but cannot measure the gas flow of the gas flowing on the wafer surface.

Therefore, when the wafer processing is not uniformly performed on the wafer surface, for example, it is difficult to find an effective solution to this problem. Further, when a trouble occurs in the wafer, for example, it is necessary to repeat trial and error to identify the cause of the trouble, which requires time.

The technique of the present disclosure appropriately measures the gas flow on the surface of the substrate. Hereinafter, a wafer processing apparatus as a substrate processing apparatus and a wafer processing method as a substrate processing method according to embodiments will be described with reference to the accompanying drawings. Like reference numerals will be given to like parts having substantially the same functions throughout the specification and the drawings, and redundant description thereof will be omitted.

<Wafer Processing Apparatus>

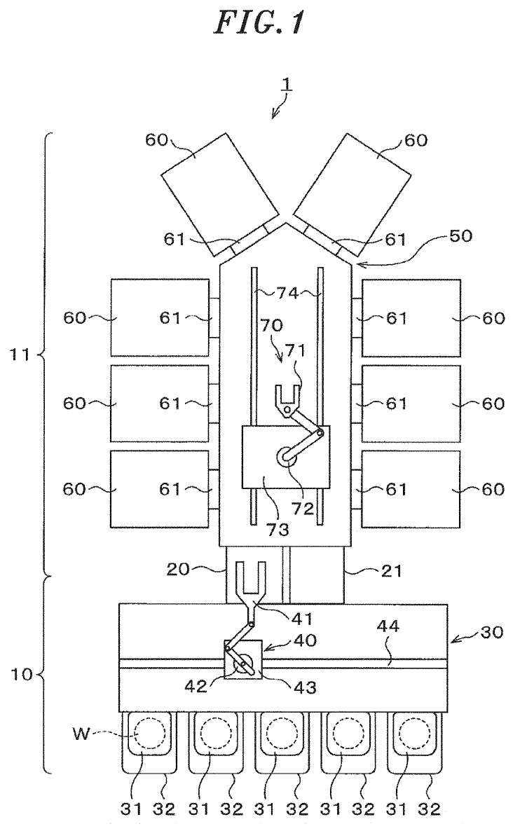

First, a wafer processing apparatus according to an embodiment will be described. FIG. 1 is a plan view showing a schematic configuration of a wafer processing apparatus 1 according to an embodiment. The wafer processing apparatus 1 performs, e.g., etching, film formation, diffusion, or the like, on the wafer W as a substrate.

As shown in FIG. 1, the wafer processing apparatus 1 has a configuration in which an atmospheric unit 10 and a depressurization unit 11 are integrally connected through load-lock modules 20 and 21. The atmospheric unit 10 includes an atmospheric module for performing desired processing on the wafer W in an atmospheric pressure atmosphere. The depressurization unit 11 includes a depressurization module for performing desired processing on the wafer W in a depressurized atmosphere.

The load-lock modules 20 and 21 are disposed to connect a loader module 30 to be described later in the atmospheric unit 10 and a transfer module 50 to be described later in the decompression unit 11 through gate valves (not shown). The load-lock modules 20 and 21 are configured to temporarily hold the wafer W. Further, inner atmospheres of the load-lock modules 20 and 21 can be switched between an atmospheric pressure atmosphere and a depressurized atmosphere (vacuum state).

The atmospheric unit 10 includes the loader module 30 provided with a wafer transfer mechanism 40 to be described later, and a load port 32 on which a FOUP 31 capable of accommodating a plurality of wafers W is placed. Further, an orientation module (not shown) for adjusting a horizontal orientation of the wafer W, a storage module (not shown) for storing a plurality of wafers W, or the like may be disposed adjacent to the loader module 30.

The loader module 30 has a rectangular housing, and an inner atmosphere of the housing is maintained in an atmospheric pressure atmosphere. A plurality of, e.g. five, load ports 32 are arranged side by side on one longitudinal side of the housing of the loader module 30. The load-lock modules 20 and 21 are arranged side by side on the other longitudinal side of the housing of the loader module 30.

The wafer transfer mechanism 40 for transferring the wafer W is disposed in the loader module 30. The wafer transfer mechanism 40 includes a transfer arm 41 for holding and moving the wafer W, a rotatable table 42 that rotatably supports the transfer arm 41, and a rotatable table base 43 on which the rotatable table 42 is placed. A guide rail 44 extending in the longitudinal direction of the loader module 30 is disposed in the loader module 30. The rotatable table base 43 is disposed on the guide rail 44, and the wafer transfer mechanism 40 is configured to be movable along the guide rail 44.

The depressurization unit 11 includes transfer modules 50 for simultaneously transferring wafers W, and processing modules 60 for performing desired processing on the wafer W transferred from the transfer module 50. The inner atmospheres of the transfer module 50 and the processing module 60 are maintained in a depressurized atmosphere. A plurality of, e.g., eight processing modules 60 are provided for one transfer module 50. The number and the arrangement of the processing modules 60 are not limited to those described in the present embodiment, and may vary.

The transfer module 50 has a polygonal (pentagonal shape in the illustrated example) housing, and is connected to the load-lock modules 20 and 21 as described above. The transfer module 50 transfers the wafer W loaded into the load-lock module 20 to one processing module 60. The wafer W is subjected to desired processing, and then unloaded to the atmospheric unit 10 through the load-lock module 21.

The processing modules 60 perform processing such as etching, film formation, diffusion, or the like. As the processing modules 60, any module that performs processing suitable for the purpose of wafer processing can be selected. The processing modules 60 are connected to the transfer module 50 through gate valves 61. The configuration of the processing modules 60 will be described later.

A wafer transfer mechanism 70 for transferring the wafer W is disposed in the transfer module 50. The wafer transfer mechanism 70 includes a transfer arm 71 that holds and moves the wafer W, a rotatable table 72 that rotatably supports the transfer arm 71, and a rotatable table base 73 on which the rotatable table 72 is placed. A guide rail 74 extending in the longitudinal direction of the transfer module 50 is disposed in the transfer module 50. The rotatable table base 73 is disposed on the guide rail 74, and the wafer transfer mechanism 70 is configured to be movable along the guide rail 74.

In the transfer module 50, the transfer arm 71 receives the wafer W from the load-lock module 20 and transfers the wafer W to the processing module 60. The wafer W that has been subjected to the desired processing is unloaded to the load-lock module 21 while being held by the transfer arm 71.

The following is description on the wafer processing performed by the wafer processing apparatus 1 configured as described above.

First, the FOUP 31 accommodating a plurality of wafers W is placed on the load port 32.

Next, the wafer transfer mechanism 40 takes out a wafer W from the FOUP 31 and loads the wafer W into the load-lock module 20. When the wafer W is loaded into the load-lock module 20, the load-lock module 20 is sealed and depressurized. Then, the inside of the load-lock module 20 and the inside of the transfer module 50 communicate with each other.

Next, the wafer W is transferred from the load-lock module 20 to the transfer module 50 while being held by the wafer transfer mechanism 70.

Next, the gate valve 61 is opened, and the wafer W is loaded into the processing module 60 by the wafer transfer mechanism 70. Then, the gate valve 61 is closed, and the wafer W is subjected to desired processing in the processing module 60. The processing performed on the wafer W will be described later.

Next, the gate valve 61 is opened, and the wafer W is unloaded from the processing module 60 by the wafer transfer mechanism 70. Then, the gate valve 61 is closed.

Next, the wafer W is loaded into the load-lock module 21 by the wafer transfer mechanism 70. When the wafer W is loaded into the load-lock module 21, the load-lock module 21 is sealed and opened to the atmosphere. Then, the inside of the load-lock module 21 and the inside of the loader module 30 communicate with each other.

Next, the wafer W held by the wafer transfer mechanism 40 is returned from the load-lock module 21 to the FOUP 31 through the loader module 30 and accommodated therein. In this manner, a series of wafer processing in the wafer processing apparatus 1 is ended.

<Processing Module>

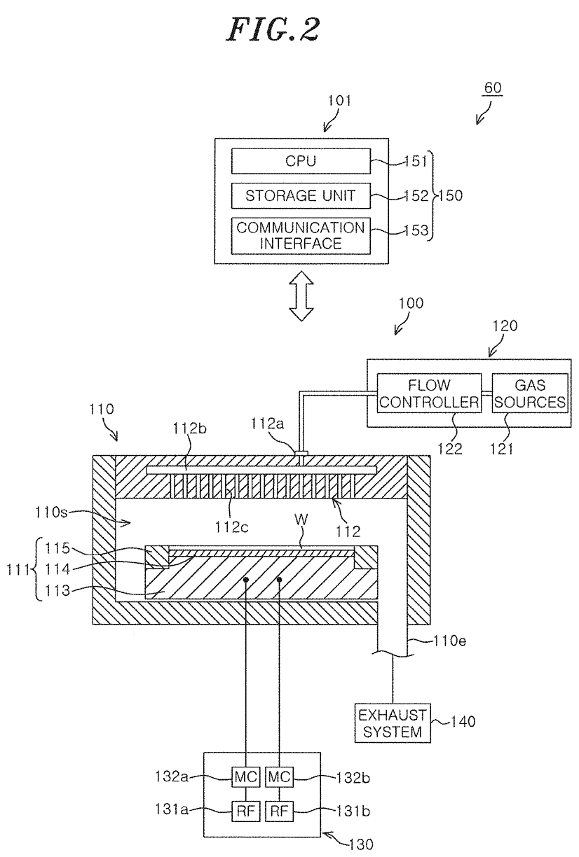

Next, the processing module 60 will be described. FIG. 2 is a vertical cross-sectional view showing a schematic configuration of the processing module 60.

As shown in FIG. 2, the processing module 60 includes a plasma processing apparatus 100 and a controller 101. The plasma processing apparatus 100 includes a plasma processing chamber 110, a gas supply unit 120, a radio frequency (RF) power supply unit 130, and an exhaust system 140. The plasma processing apparatus 100 further includes a support unit 111 and an upper electrode shower head 112. The support unit 111 is disposed in a lower area of a plasma processing space 110s in the plasma processing chamber 110. The upper electrode shower head 112 is disposed above the support unit 111 and may function as a part of a ceiling of the plasma processing chamber 110.

The support unit 111 is configured to support the wafer W in the plasma processing space 110s. In one embodiment, the support unit 111 includes a lower electrode 113, an electrostatic chuck 114 as a mounting table, and an edge ring 115. The electrostatic chuck 114 is disposed on the lower electrode 113 and is configured to support the wafer W on an upper surface of the electrostatic chuck 114. The edge ring 115 is disposed to surround the wafer W on an upper surface of a peripheral edge of the lower electrode 113. Although it is not illustrated, in one embodiment, the support unit 111 may include lifter pins that penetrate through the support unit 111 and are configured to be vertically movable while being in contact with a backside of the wafer W. Further, although it is not illustrated, in one embodiment, the support unit 111 may include a temperature control module configured to adjust at least one of the electrostatic chuck 114 and the wafer W to a target temperature. The temperature control module may include a heater, a flow path, or a combination thereof. A temperature control fluid such as a coolant or a heat transfer gas flows through the flow path.

The upper electrode shower head 112 is configured to supply one or more processing gases from the gas supply unit 120 to the plasma processing space 110s. In one embodiment, the upper electrode shower head 112 has a gas inlet 112a, a gas diffusion space 112b, and a plurality of gas outlets 112c. The gas inlet 112a is in fluid communication with the gas supply unit 120 and the gas diffusion space 112b. The gas outlets 112c is in fluid communication with the gas diffusion space 112b and the plasma processing space 110s. In one embodiment, the upper electrode shower head 112 is configured to supply one or more processing gases from the gas inlet 112a to the plasma processing space 110s through the gas diffusion space 112b and the gas outlets 112c.

The gas supply unit 120 may include one or more gas sources 121 and one or more flow controllers 122. In one embodiment, the gas supply unit 120 is configured to supply one or more processing gases from the corresponding gas sources 121 to the gas inlet 112a through the corresponding flow controllers 122. Each of the flow controllers 122 may include, e.g., a mass flow controller or a pressure-control type flow rate controller. Further, the gas supply unit 120 may include one or more flow modulation devices for modulating or pulsing the gas flow of one or more processing gases.

The RF power supply unit 130 is configured to supply an RF power, e.g., one or more RF signals, to one or more electrodes, i.e., either one or both of the lower electrode 113 and the upper electrode shower head 112. Therefore, plasma is generated from one or more processing gases supplied to the plasma processing space 110s. Accordingly, the RF power supply unit 130 may function as at least a part of a plasma generation unit configured to generate plasma from one or more processing gases in the plasma processing chamber. In one embodiment, the RF power supply unit 130 includes two RF generation units 131a and 131b, and two matching circuits (MC) 132a and 132b. In one embodiment, the RF power supply unit 130 is configured to supply a first RF signal from the first RF generation unit 131a to the lower electrode 113 through the first matching circuit 132a. For example, the first RF signal may have a frequency within a range of 27 MHz to 100 MHz.

Further, in one embodiment, the RF power supply unit 130 is configured to supply a second RF signal from the second RF generation unit 131b to the lower electrode 113 through the second matching circuit 132b. For example, the second RF signal may have a frequency within a range of 400 kHz to 13.56 MHz. A direct current (DC) pulse generation unit may be used instead of the second RF generation unit 131b.

Although it is not illustrated, other embodiments of the present disclosure may be considered. For example, in an alternative embodiment, the RF power supply unit 130 may be configured to supply the first RF signal from the RF generation unit to the lower electrode 113 and supply the second RF signal from another RF generation unit to the lower electrode 113, and supply a third RF signal from still another RF generation unit to the lower electrode 113. In another alternative embodiment, a DC voltage may be applied to the upper electrode shower head 112.

In various embodiments, the amplitude of one or more RF signals (i.e., the first RF signal, the second RF signal, and the like) may be pulsed or modulated. The amplitude modulation may include pulsing of the RF signal amplitude between an on state and an off state, or between two or more different on states.

The exhaust system 140 may be connected to, e.g., a gas exhaust port 110e disposed at a bottom portion of the plasma processing chamber 110. The exhaust system 140 may include a pressure valve and a vacuum pump. The vacuum pump may include a turbo molecular pump, a roughing pump or a combination thereof.

In one embodiment, the controller 101 processes computer-executable instructions for causing the plasma processing apparatus 100 to perform various processes described in the present disclosure. The controller 101 may be configured to control the respective components of the plasma processing apparatus 100 to perform various steps described herein. In one embodiment, the controller 101 may be partially or entirely included in the plasma processing apparatus 100. The controller 101 may include, e.g., a computer 150. The computer 150 may include, e.g., a central processing unit (CPU) 151, a storage unit 152, and a communication interface 153. The processing unit 151 may be configured to perform various control operations based on programs stored in the storage unit 152. The storage unit 152 may include a random access memory (RAM), a read only memory (ROM), a hard disk drive (HDD), a solid state drive (SSD), or a combination thereof. The communication interface 153 may communicate with the plasma processing apparatus 100 through a communication line such as a local area network (LAN) or the like.

While various embodiments have been described above, the present disclosure is not limited to the above-described embodiments, and various additions, omissions, substitutions and changes may be made. Further, other embodiments can be implemented by combining elements in different embodiments.

<Wafer Processing>

The following is description on wafer processing performed by the processing module 60 configured as described above. The processing module 60 performs the processing such as etching, film formation, diffusion, or the like on the wafer W.

First, the wafer W is loaded into the plasma processing chamber 110 and placed on the electrostatic chuck 114 by vertically moving the lifter pins. Then, the wafer W is electrostatically attracted and held on the electrostatic chuck 114 by a Coulomb force generated by applying a DC voltage to the electrode of the electrostatic chuck 114. After the wafer W is loaded, the plasma processing chamber 110 is depressurized to a predetermined vacuum level by the exhaust system 140.

Next, the processing gas is supplied from the gas supply unit 120 to the plasma processing space 110s through the upper electrode shower head 112. Further, the RF power supply unit 130 supplies a radio frequency power HF for plasma generation to the lower electrode 113. Accordingly, the processing gas is excited, and plasma is generated. At this time, the RF power supply unit 130 may supply a radio frequency power LF for ion attraction. Then, the wafer W is subjected to plasma processing by the action of the generated plasma.

During the plasma processing, the temperature of the wafer W attracted and held on the electrostatic chuck 114 is adjusted by the temperature control module. At this time, in order to efficiently transfer heat to the wafer W, a heat transfer gas such as He gas, Ar gas, or the like is supplied toward the backside of the wafer W attracted and held on the upper surface of the electrostatic chuck 114.

In order to end the plasma processing, first, the supply of the radio frequency power HF from the RF power supply unit 130 and the supply of the processing gas by the gas supply unit 120 are stopped. When the radio frequency power LF is supplied during the plasma processing, the supply of the radio frequency power LF is also stopped. Next, the supply of the heat transfer gas to the backside of the wafer W is stopped, and the attraction and holding of the wafer W on the electrostatic chuck 114 is stopped.

Then, the wafer W is raised by the lifter pins and separated from the electrostatic chuck 114. At this time, an antistatic treatment of the wafer W may be performed. Then, the wafer W is unloaded from the plasma processing chamber 110, and a series of plasma processing for the wafer W is ended.

<Evaluation Wafer>

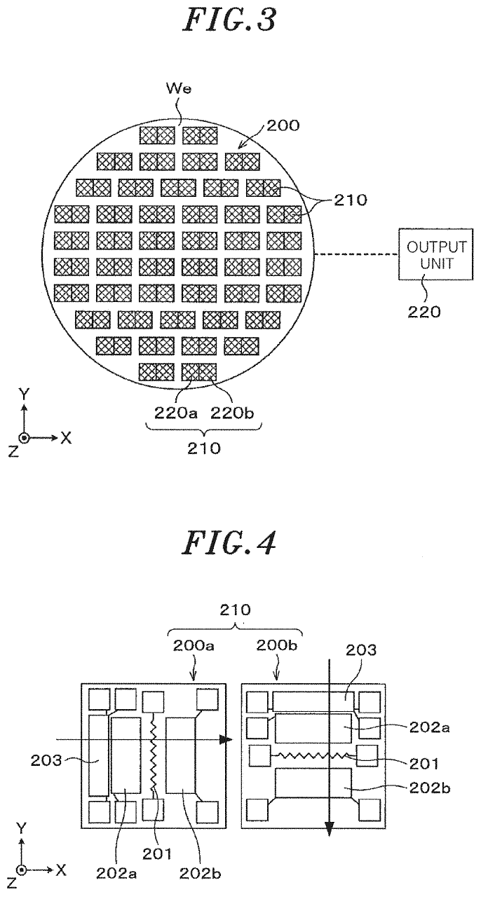

In the above-described embodiments, in order to perform the wafer processing uniformly on the wafer surface, it is important to appropriately control the flow of the processing gas on the surface of the wafer W. Therefore, the magnitude and the direction of flow of the processing gas are measured using a wafer We for evaluating a gas flow (hereinafter, referred to as “evaluation wafer We”). FIG. 3 is a plan view showing a schematic configuration of the evaluation wafer We according to an embodiment.

As shown in FIG. 3, multiple flow sensors 200 are disposed on the surface of the evaluation wafer We. As the flow sensors 200, micro electro mechanical system sensors (MEMS) are used, for example. Since the MEMS sensors are thin and small, a large number of flow sensors 200 can be disposed on the evaluation wafer We.

As shown in FIG. 4, the flow sensor 200 that is the MEMS sensor is a thermal sensor including a heater 201, a pair of thermopiles 202a and 202b, and a temperature sensor 203. The thermopiles 202a and 202b are symmetrically disposed with respect to the heater 201. The temperature sensor 203 measures an ambient temperature of the flow sensor 200.

In the flow sensor 200, the temperature distribution of the thermopiles 202a and 202b with respect to the heater 201 are symmetrical where there is no gas flow. On the other hand, when there is a gas flow, the temperature of the thermopile 202a from which the wind of the heater 201 blows is low, and the temperature of the thermopile 202b to which the wind of the heater 201 reaches is high and, thus, the balance of temperature is lost. The gas flow can be measured by detecting the temperature difference between the thermopiles 202a and 202b as an electromotive force.

The evaluation wafer We is provided with two flow sensors 200 and 200 forming one pair. In the following description, one flow sensor 200 is referred to as “first flow sensor 200a” and the other flow sensor 200 is referred to as “second flow sensor 200b.” Further, the pair of flow sensors 200a and 200b is referred to as “sensor pair 210.”

The first flow sensor 200a measures gas flow of a gas in a first direction (X-axis direction in the example of FIG. 4). In other words, in the first flow sensor 200a, the heater 201 and the thermopiles 202a and 202b are arranged side by side in the X-axis direction. The second flow sensor 200b measures gas flow of a gas in a second direction (Y-axis direction in the example of FIG. 4) perpendicular to the first direction. In other words, in the second flow sensor 200b, the heater 201 and the thermopiles 202a and 202b are arranged side by side in the Y-axis direction. Arrows in FIG. 4 indicate gas flows.

In the sensor pair 210, the first flow sensor 200a and the second flow sensor 200b measure the gas flows perpendicular to each other. Then, the magnitudes and the directions of the gas flows at the position where the sensor pair 210 is disposed can be measured by combining the measurement results (gas flow vectors) of the first flow sensor 200a and the second flow sensor 200b.

As shown in FIG. 3, multiple sensor pairs 210 are arranged on the entire surface of the evaluation wafer We. Each sensor pair 210 measures the magnitude and the direction of flow of the gas. The measurement result of each sensor pair 210 is outputted to an output unit 220 through, e.g., a wireless LAN, although it is not limited thereto. The output unit 220 visualizes the magnitude and the direction of the gas flow measured by each sensor pair 210. Accordingly, the gas flow on the surface of the evaluation wafer We can be detected.

<Gas Flow Measuring Method>

Next, a processing gas flow measuring method using the evaluation wafer We in the processing module 60 will be described.

First, the evaluation wafer We is loaded into the plasma processing chamber 110 and placed on the electrostatic chuck 114 by vertically moving the lifter pins. Then, the evaluation wafer We is electrostatically attracted and held on the electrostatic chuck 114 by a Coulomb force generated by applying a DC voltage to the electrode of the electrostatic chuck 114. After the evaluation wafer We is loaded, the pressure in the plasma processing chamber 110 is decreased to a predetermined vacuum level by the exhaust system 140.

Next, the processing gas is supplied from the gas supply unit 120 into the plasma processing space 110s through the upper electrode shower head 112. In the evaluation wafer We, the magnitudes and the directions of the processing gas flow on the surface of the evaluation wafer We are measured by the multiple flow sensors 200 (multiple sensors pairs 210). At this time, a radio frequency power is not applied to the lower electrode 113. In other words, plasma is not generated.

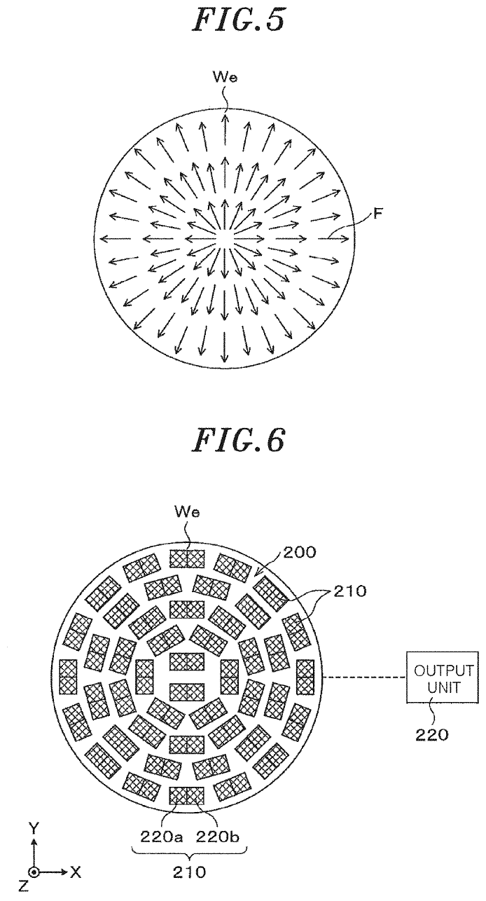

The measurement results obtained by the flow sensors 200 are outputted to the output unit 220. In the output unit 220, the magnitudes and the directions of the processing gas flow are visualized. FIG. 5 shows an example of the processing gas flow on the evaluation wafer We. In FIG. 5, arrows indicate flow directions F of the processing gas; the sizes of the arrows indicate the magnitudes of flows of the processing gas; and the directions of the arrows indicate the flow directions of the processing gas.

When the measurement of the processing gas flow is ended, the supply of the processing gas by the gas supply unit 120 is stopped. Next, the attraction and holding of the evaluation wafer We on the electrostatic chuck 114 is stopped.

Then, the evaluation wafer We is raised by the lifter pins and separated from the electrostatic chuck 114. At this time, an antistatic treatment of the wafer W may be performed. Then, the evaluation wafer We is unloaded from the plasma processing chamber 110, and a series of processing gas flow measuring processes is ended.

In accordance with the above-described embodiments, the magnitudes and the directions of flows of the processing gas on the evaluation wafer We can be appropriately measured using the multiple flow sensors 200 (the multiple sensors pairs 210). By measuring the flow of the processing gas, when the product wafer W is processed, for example, the processing gas can be controlled such that the processing gas flows appropriately on the wafer surface. Accordingly, the desired processing can be appropriately and uniformly performed on the wafer W. Further, the processing gas can be controlled such that the concentration of the processing gas becomes high locally on the wafer surface. Accordingly, it is possible to improve defects that occur locally during the processing of the wafer W. In any case, the shapes and the dimensions of the respective components (hardware) in the processing module 60 can be optimized.

By measuring the magnitude and the direction of the processing gas flow before and after the processing of the product wafer W and comparing the measurement results, it is possible to identify the cause of a trouble, if occurs. Specifically, in one processing module 60, initial values of the magnitudes and the directions of the processing gas flows are measured before the product wafer W is processed. After the product wafer W is processed, the magnitudes and the directions of the processing gas flows are measured. Then, the cause of the trouble can be identified by comparing the initial values measured before the processing with the measurement results obtained after the processing. Moreover, it is not necessary to repeat trial and error as in the conventional case, and the cause of the trouble can be identified at an early stage.

There are various causes of troubles, e.g., deposits adhered to the plasma processing chamber 110, clogging of the gas outlet 112c of the upper electrode shower head 112, and the like. The flow of the processing gas on the evaluation wafer We is different between the case of the trouble of the plasma processing chamber 110 and the case of the trouble of the upper electrode shower head 112. Therefore, in the present embodiment, the cause of the trouble can be identified by measuring the flow of the processing gas. In order to identify the cause of the trouble, not only the flow of the processing gas but also other data such as an etching rate at the time of the trouble and the like may be used.

When a sensor that is affected by a specific heat, such as a MEMS sensor, is used as the flow sensor 200, the output from the flow sensor 200 varies when the gas components in the processing module 60 change. For example, when the processing gas is mixed with a residual gas in a previous processing or with the gas generated from reaction products deposited in the processing module 60, the output from the flow sensor 200 varies depending on the specific heat of the mixed gas. Therefore, when abnormality occurs in the processing of the wafer W, it is possible to specify the type of the mixed gas by comparing the output from the flow sensor 200 at that time and the output from the flow sensor 200 at the time of supplying only the processing gas into the processing module 60.

### Other Embodiments

In the evaluation wafer We, the arrangement and the number of the flow sensors 200 are not limited to the example shown in FIG. 3. For example, as shown in FIG. 6, the multiple sensor pairs 210 may be arranged at an equal interval along concentric circles on the evaluation wafer We. Even in that case, the magnitudes and the directions of flows of the processing gas at the positions where the sensor pairs 210 are disposed can be measured, which makes it possible to measure the gas flows on the surface of the evaluation wafer We.

Further, when the evaluation wafer We is transferred to the processing module 60, the multiple flow sensors 200 may be used to measure the magnitudes and the directions of flows of the gas on the surface of the evaluation wafer We.

In the wafer processing apparatus 1, the pressure in the transfer module 50 is higher than the pressure in the processing module 60. For example, when the etching is performed in the processing module 60, particles are generated in the plasma processing chamber 110. By setting the pressure in the transfer module 50 to a positive pressure, the inflow of the particles into the transfer module 50 can be suppressed. In that case, the gate valve is opened to load the evaluation wafer We into the processing module 60, a unidirectional gas flow is generated from the transfer module 50 toward the processing module 60.

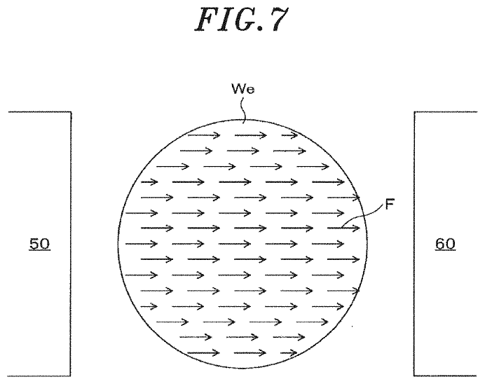

Here, when the evaluation wafer We is loaded into the processing module 60, the gas flow directed from the transfer module 50 toward the processing module 60 may be disturbed or convection occurs in the gas flow depending on a transfer speed. Therefore, when the evaluation wafer We is loaded into the processing module 60, the magnitudes and the directions of the gas flows on the surface are measured using the multiple flow sensors 200. Then, the transfer speed of the evaluation wafer We and the acceleration of the transfer speed are optimized such that a unidirectional gas flow F is generated from the transfer module 50 toward the processing module 60 as shown in FIG. 7.

As described above, by optimizing the transfer speed and the acceleration at the time of loading the evaluation wafer We into the processing module 60, it is possible to optimize the gas flow and to suppress the inflow of particles in the processing module 60 into the transfer module 50.

Similarly, when the evaluation wafer We is unloaded from the processing module 60, the magnitudes and the directions of the gas flows on the surface of the evaluation wafer We can be measured to optimize the transfer speed and the acceleration.

If a large amount of gas flows from the transfer module 50 to the processing module 60, the inner atmospheric conditions in the processing module 60 may be changed. In that case, time is required to adjust the inner atmosphere before the processing is performed in the processing module 60. By optimizing the transfer speed and the acceleration of the evaluation wafer We in consideration of the gas flow of the gas, the atmosphere in the processing module 60 can be maintained and the throughput of the wafer processing can be improved.

In the above-described embodiments, the magnitudes and the directions of the gas flows on the surface of the evaluation wafer We are measured. However, the multiple flow sensors 200 may be disposed on the surface of a product wafer W in order to measure the magnitudes and the flow directions of the gas flows on the surface of the wafer W. In that case, when the wafer W is processed in the processing module 60, the processing gas flow can be controlled in real time based on the measurement result. Further, when the wafer W is transferred between the transfer module 50 and the processing module 60, the transfer speed and the acceleration can be optimized in real time based on the measurement result.

In the above-described embodiments, the multiple flow sensors 200 are disposed on the surface of the evaluation wafer We. However, the flow sensors 200 (the sensor pairs 210) may be disposed at each component of the processing module 60. For example, the flow sensors 200 (the sensor pairs 210) may be disposed on an inner surface of the plasma processing chamber 110, the bottom surface of the upper electrode shower head 112, the upper surface of the electrostatic chuck 114, the upper surface of the edge ring 115, or the like. In that case, the magnitude and the direction of the processing gas flow in the processing module 60 can be measured.

In the above-described embodiments, the MEMS sensor is used as the flow sensor 200. However, the flow sensor 200 is not limited thereto, and may be any flow sensor capable of measuring gas flow of a gas.

In the above-described embodiments, the processing such as etching, film formation, diffusion, or the like is performed in the processing module 60. However, the evaluation wafer We and the gas flow measuring method of the present disclosure may be applied to another processing as long as it is wafer processing using a gas.

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A substrate processing method comprising:
(a) placing a substrate on a substrate support disposed in a chamber, the substrate having a plurality of flow sensors on a surface of the substrate;
(b) supplying a processing gas into the chamber; and
(c) measuring magnitudes and directions of flows of the processing gas on the surface of the substrate using the plurality of flow sensors.

2. The substrate processing method of claim 1, wherein the substrate is an evaluation substrate for measuring flows of the processing gas.

3. The substrate processing method of claim 1, wherein the flow sensors are MEMS flow sensors.

4. The substrate processing method of claim 1, wherein the plurality of flow sensors include multiple sensor pairs, each pair having a first flow sensor configured to measure gas flow of the processing gas in a first direction, and a second flow sensor configured to measure gas flow of the processing gas in a second direction perpendicular to the first direction, and
wherein in (c), the magnitudes and the directions of flows of the processing gas at the positions where the sensor pairs are disposed are measured by the sensor pairs.

5. The substrate processing method of claim 1, further comprising:
(d) processing a product substrate; and
(e) performing (a) to (c) to evaluate the magnitudes and the directions of flows of the processing gas,
wherein (e) includes:
(e1) performing (a) to (c) prior to (d) to measure initial values of the magnitudes and the directions of flows of the processing gas;
(e2) performing (a) to (c) after (d); and
(e3) comparing the initial values measured in (e1) with the measurement results of (e2).

6. The substrate processing method of claim 1, further comprising:
(f) processing a product substrate; and
(g) performing (a) to (c) to evaluate components contained in the processing gas based on outputs of the flow sensors,
wherein (g) includes:
(g1) performing (a) to (c) prior to (f) to measure initial values of the outputs of the flow sensors;
(g2) performing (a) to (c) after (f) to measure the outputs of the flow sensors; and
(g3) comparing the initial values measured in (g1) with the outputs measured in (g2).

7. The substrate processing method of claim 1, further comprising, prior to (a), measuring magnitudes and directions of flows of a gas on the surface of the substrate using the flow sensors at the time of transferring the substrate to the chamber.

8. The substrate processing method of claim 1, further comprising, after (c), measuring magnitudes and directions of flows of the gas on the surface of the substrate using the flow sensors at the time of transferring the substrate from the chamber.

9. A gas flow evaluation substrate used for measuring gas flows on a surface of a substrate, comprising:
a plurality of flow sensors on a surface of the evaluation substrate.

10. The gas flow evaluation substrate of claim 9, wherein the flow sensors are MEMS flow sensors.

11. The gas flow evaluation substrate of claim 9, wherein the flow sensors include multiple sensor pairs, each pair including a first flow sensor configured to measure gas flow of the processing gas in a first direction, and a second flow sensor configured to measure gas flow of the processing gas in a second direction perpendicular to the first direction.

12. The gas flow evaluation substrate of claim 9, wherein the plurality of sensor pairs are arranged on the surface of the evaluation wafer in a first direction.

13. The gas flow evaluation substrate of claim 9, wherein the plurality of sensor pairs are arranged at an equal interval along concentric circles on the evaluation wafer.

14. A substrate processing apparatus comprising:
a chamber having a gas supply port and a gas discharge port; and
a controller,
wherein the controller controls the substrate processing apparatus to perform processes including:
(a) placing a substrate on a substrate support disposed in the chamber, the substrate having a plurality of flow sensors on a surface of the substrate;
(b) supplying a processing gas into the chamber; and
(c) measuring magnitudes and directions of flows of the processing gas on the surface of the substrate using the flow sensors.
